(19) United States
(12) Patent Application Publication
(10) Pub. No.: US 2025/0215279 A1
(43) Pub. Date: Jul. 3, 2025

(54) PRESSURE-SENSITIVE ADHESIVE TAPE, METHOD FOR PRODUCING THE SAME, AND METHOD FOR USING THE SAME

(71) Applicant: NAN YA PLASTICS CORPORATION, TAIPEI (TW)

(72) Inventors: TE-CHAO LIAO, TAIPEI (TW); CHUN-CHE TSAO, TAIPEI (TW); PEI-YU CHIANG, TAIPEI (TW)

(21) Appl. No.: 18/604,437

(22) Filed: Mar. 13, 2024

(30) Foreign Application Priority Data
Dec. 27, 2023 (TW) 112150896

(51) Int. Cl. C09J 7/38

(52) U.S. Cl. CPC C09J 7/385; C09J 2301/302; C09J 2433/00

(57) ABSTRACT

A pressure-sensitive adhesive tape, a method for producing the same, and a method for using the same are provided. The pressure-sensitive adhesive tape includes a support layer, an adhesive layer, and a peeling layer. Solid components of the adhesive layer include a self-crosslinking acrylic resin, acrylate monomers or oligomers of the acrylate monomers, an isocyanate cross-linking agent, and a photo-initiator. Before the adhesive layer is irradiated by ultraviolet light, the acrylate monomers or the oligomers do not undergo a cross-linking and curing reaction. After the adhesive layer is irradiated by the ultraviolet light, the photo-initiator generates free radicals with abilities to initiate polymerization, and the self-crosslinking acrylic resin, the acrylate monomers or the oligomers, and the isocyanate cross-linking agent undergo the cross-linking and curing reaction, so that an adhesion of the adhesive layer is reduced.

### CROSS-REFERENCE TO RELATED PATENT APPLICATION

This application claims the benefit of priority to Taiwan Patent Application No. 112150896, filed on Dec. 27, 2023. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a pressure-sensitive adhesive tape, and more particularly to a pressure-sensitive adhesive tape, a method for producing the same, and a method for using the same. The pressure-sensitive adhesive tape can be de-glued by ultraviolet light.

### BACKGROUND OF THE DISCLOSURE

In the related art, during a semiconductor wafer processing process, a wafer is processed into multiple small dice (or chips) containing integrated circuits through a cutting operation (or dicing operation), such as laser dicing, plasma dicing, scribing dicing, or saw dicing. The dice are then separated individually for use in packaging or in larger circuits in an unpackaged form.

In the cutting operation, a pressure-sensitive adhesive tape (e.g., UV-curable tape) is often used to mount the wafer to be diced onto a carrier substrate. The carrier substrate allows UV light to penetrate therethrough to irradiate and cure the pressure-sensitive adhesive tape, so as to facilitate subsequent pickup of the dice.

However, the conventional pressure-sensitive adhesive tape used for adhering to the carrier substrate to be cut has insufficient adhesive strength, leading to issues such as dice drop-off or material scattering during the cutting operation. After UV exposure, the adhesive strength between the pressure-sensitive adhesive tape and the carrier substrate becomes overly high. Accordingly, the pressure-sensitive adhesive tape is difficult to peel off from the carrier substrate without leaving residual adhesive. In other words, after UV exposure, the pressure-sensitive adhesive tape exhibits reduced adhesive strength, but not enough to allow the dice (or chips) to drop off. Therefore, the usage of the conventional pressure-sensitive adhesive tape in the cutting operation for the semiconductor wafer processing process still has room for improvement.

### SUMMARY OF THE DISCLOSURE

In response to the above-referenced technical inadequacies, the present disclosure provides a pressure-sensitive adhesive tape, a method for producing the same, and a method for using the same.

The pressure-sensitive adhesive tape of the present disclosure can overcome the issues of dice drop-off during the semiconductor cutting operation and the dice being difficult to be peeled off from the carrier substrate after UV exposure. The pressure-sensitive adhesive tape provided by the present disclosure can be de-glued by UV light and is particularly suitable for use in a semiconductor wafer processing process, so as to facilitate pickup of the dice.

In order to solve the above-mentioned problems, one of the technical aspects adopted by the present disclosure is to provide a pressure-sensitive adhesive tape that includes a support layer, an adhesive layer, and a peeling layer. The adhesive layer is formed on a side surface of the support layer. Solid components of the adhesive layer include a self-crosslinking acrylic resin, acrylate monomers or oligomers of the acrylate monomers, an isocyanate cross-linking agent, and a photo-initiator. The peeling layer is peelably formed on a side surface of the adhesive layer away from the support layer. Before the adhesive layer is irradiated by ultraviolet light, the acrylate monomers or the oligomers do not undergo a cross-linking and curing reaction. After the adhesive layer is irradiated by the ultraviolet light, the photo-initiator generates free radicals with abilities to initiate polymerization, and the self-crosslinking acrylic resin, the acrylate monomers or the oligomers, and the isocyanate cross-linking agent undergo the cross-linking and curing reaction, so that an adhesion of the adhesive layer is reduced.

In one of the possible or preferred embodiments, based on a total weight of the solid components of the adhesive layer being 100 wt %, a content of the self-crosslinking acrylic resin ranges from 50 wt % to 95 wt %, a content of the acrylate monomers or the oligomers ranges from 1 wt % to 40 wt %, a content of the isocyanate cross-linking agent ranges from 0.1 wt % to 10 wt %, and a content of the photo-initiator ranges from 0.1 wt % to 10 wt %.

In one of the possible or preferred embodiments, the content of the self-crosslinking acrylic resin ranges from 50 wt % to 90 wt %, the content of the acrylate monomers or the oligomers ranges from 5 wt % to 35 wt %, the content of the isocyanate cross-linking agent ranges from 0.1 wt % to 5 wt %, and the content of the photo-initiator ranges from 0.1 wt % to 5 wt %.

In one of the possible or preferred embodiments, the self-crosslinking acrylic resin is polymerized by at least one of the following monomer components: 2-hydroxyethyl acrylate (HEA), methyl acrylate (MA), 2-methoxyethyl acrylate (MEA), acrylic acid (AA), acrylonitrile, 2-ethylhexyl methacrylate (EHA), 2-phenoxyethyl acrylate (PEA), and butyl acrylate (BA).

In one of the possible or preferred embodiments, a molecular structure of the self-crosslinking acrylic resin has at least one of the following functional groups: a propylene group, a hydroxyl group, and a carboxyl group.

In one of the possible or preferred embodiments, the acrylate monomers or the oligomers are selected from the group consisting of: bisphenol A dimethacrylate, (1-methylethylidene)bis(4,1-phenyleneoxy-2,1-ethanediyl) diacrylate, ethoxylated bisphenol A dimethacrylate, iso-bornyl acrylate, and urethane acrylate.

In one of the possible or preferred embodiments, the isocyanate cross-linking agent is a diisocyanate, and the diisocyanate is selected from the group consisting of: toluene diisocyanate (TDI), isophorone diisocyanate (IPDI), diphenylmethane diisocyanate (MDI), dicyclohexylmethane diisocyanate (H₁₂MDI), and lysine diisocyanate (LDI).

In one of the possible or preferred embodiments, the photo-initiator is selected from the group consisting of: benzophenone, 2-hydroxy-2-methyl-1-propiophenone, 2,2-dimethoxy-1,2-diphenylethan-1-one, 1-hydroxycyclohexyl phenyl ketone, 2,4,6-trimethyl benzoyl diphenyl phosphine oxide, n-phenylglycine, 9-phenylacridine, benzoin, benzyl dimethyl ketal, 4,4′-bis(diethylamino) benzophenone, 2,4,5-tri aryl imidazole dimer.

In order to solve the above-mentioned problems, another one of the technical aspects adopted by the present disclosure is to provide a method for producing a pressure-sensitive adhesive tape. The method includes: providing a peeling layer; applying a coating material on a side surface of the peeling layer. The coating material includes solid components and at least a solvent component for mixing the solid components. The solid components include a self-crosslinking acrylic resin, acrylate monomers or oligomers of the acrylate monomers, an isocyanate cross-linking agent, and a photo-initiator. The solvent component is at least one of ethyl acetate and methyl ethyl ketone. A weight ratio between the solvent component and the solid components ranges from 5:95 to 30:70. The method further includes: removing the solvent component from the coating material to form an adhesive layer on the side surface of the peeling layer; and attaching a support layer on a side surface of the adhesive layer away from the peeling layer to form the pressure-sensitive adhesive tape.

The peeling layer is peelable from the adhesive layer, so that the adhesive layer is capable of being exposed to an external environment and being bonded to a substrate material to be cut. Before the adhesive layer is irradiated by ultraviolet light, the acrylate monomers or the oligomers do not undergo a cross-linking and curing reaction.

After the adhesive layer is irradiated by the ultraviolet light, the photo-initiator generates free radicals with abilities to initiate polymerization, and the self-crosslinking acrylic resin, the acrylate monomers or the oligomers, and the isocyanate cross-linking agent undergo the cross-linking and curing reaction, so that an adhesion of the adhesive layer is reduced.

In order to solve the above-mentioned problems, another one of the technical aspects adopted by the present disclosure is to provide a method for using a pressure-sensitive adhesive tape. The method includes providing the pressure-sensitive adhesive tape as mentioned above; peeling off the peeling layer of the pressure-sensitive adhesive tape from the side surface of the adhesive layer, so that the adhesive layer is exposed to an external environment; providing a substrate material to be cut, and orienting the adhesive layer of the pressure-sensitive adhesive tape to face toward the substrate material to be cut; attaching the adhesive layer of the pressure-sensitive adhesive tape to the substrate material to be cut, in which a first peeling strength between the adhesive layer and the substrate material to be cut is 200 to 2,500 gf/inch; performing a cutting operation on the substrate material to be cut to form a substrate material that has been cut; and irradiating the adhesive layer of the pressure-sensitive adhesive tape by an ultraviolet light source, so that the photo-initiator generates the free radicals with the abilities to initiate the polymerization, and the self-crosslinking acrylic resin, the acrylate monomers or the oligomers, and the isocyanate cross-linking agent undergo the cross-linking and curing reaction so as to reduce the adhesion of the adhesive layer. After being irradiated by the ultraviolet light source, a second peeling strength between the adhesive layer and the substrate material is 10 to 75 gf/inch.

In one of the possible or preferred embodiments, a wavelength of the ultraviolet light source ranges from 300 nanometers to 380 nanometers, an irradiation energy of the ultraviolet light source irradiated on the adhesive layer is greater than 300 mJ/cm² and less than 2,000 mJ/cm², and an irradiation time of the ultraviolet light source irradiated on the adhesive layer ranges from 5 seconds to 2 minutes.

Therefore, in the pressure-sensitive adhesive tape, the method for producing the same, and the method for using the same provided by the present disclosure, by virtue of “solid components of the adhesive layer including a self-crosslinking acrylic resin, acrylate monomers or oligomers of the acrylate monomers, an isocyanate cross-linking agent, and a photo-initiator,” and “before the adhesive layer is irradiated by ultraviolet light, the acrylate monomers or the oligomers not undergoing a cross-linking and curing reaction,” and “after the adhesive layer is irradiated by the ultraviolet light, the photo-initiator generating free radicals with abilities to initiate polymerization, and the self-crosslinking acrylic resin, the acrylate monomers or the oligomers, and the isocyanate cross-linking agent undergo the cross-linking and curing reaction, so that an adhesion of the adhesive layer is reduced,” the pressure-sensitive adhesive tape of the present disclosure can overcome the issues of dice drop-off during the semiconductor cutting operation and the dice being difficult to be peeled off from the carrier substrate after UV exposure.

The pressure-sensitive adhesive tape provided by the present disclosure can be de-glued by UV light and is particularly suitable for use in a semiconductor wafer processing process, so as to facilitate pickup of the dice.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is schematic view of a pressure-sensitive adhesive tape according to an embodiment of the present disclosure;

FIG. 2A is a schematic view of step S110 of a method for using the pressure-sensitive adhesive tape according to the embodiment of the present disclosure;

FIG. 2B is a schematic view of step S120 of the method for using the pressure-sensitive adhesive tape according to the embodiment of the present disclosure;

FIG. 2C is a schematic view of step S130 of the method for using the pressure-sensitive adhesive tape according to the embodiment of the present disclosure;

FIG. 2D is a schematic view of step S140 of the method for using the pressure-sensitive adhesive tape according to the embodiment of the present disclosure;

FIG. 2E is a schematic view of step S150 of the method for using the pressure-sensitive adhesive tape according to the embodiment of the present disclosure; and

FIG. 2F is a schematic view of step S160 of the method for using the pressure-sensitive adhesive tape according to the embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### Pressure-Sensitive Adhesive Tape

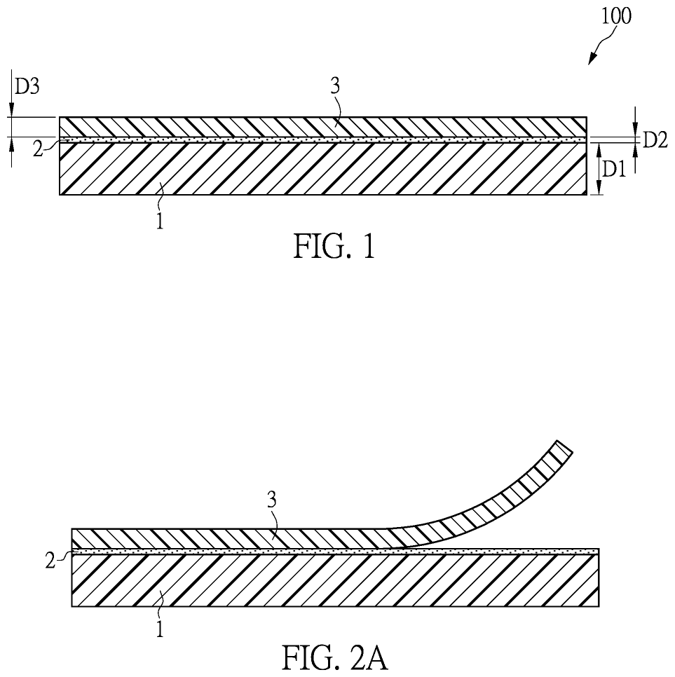

Referring to FIG. 1, an embodiment of the present disclosure provides a pressure-sensitive adhesive tape 100 that can be de-glued by UV light, and the pressure-sensitive adhesive tape 100 is suitable for a component cutting operation, especially for a wafer cutting operation (i.e., wafer dicing operation) or a packaging component cutting operation during a semiconductor process, but the present disclosure is not limited thereto.

In the semiconductor process, the component to be cut attached to the pressure-sensitive adhesive tape 100 can be, for example, a wafer, a light emitting diode substrate (LED substrate), a glass substrate, or a ceramic substrate. Both the wafer and the LED substrate can be cut into multiple small dice (or chips) containing integrated circuits through the cutting operation.

Referring to FIG. 1, the pressure-sensitive adhesive tape 100 of the embodiment of the present disclosure includes a support layer 1, an adhesive layer 2, and a peeling layer 3 stacked in sequence from bottom to top. That is, the adhesive layer 2 is formed on a side surface of the support layer 1 (e.g., an upper surface of the support layer 1 shown in FIG. 1), and the peeling layer 3 is formed on a side surface of the adhesive layer 2 away from the support layer 1 (e.g., an upper surface of the adhesive layer 2 shown in FIG. 1), but the present disclosure is not limited thereto. In practical applications, the arrangement of the support layer 1, the adhesive layer 2, and the peeling layer 3 of the pressure-sensitive adhesive tape 100 can be changed according to actual requirements. For example, the support layer 1 can be disposed at the topmost layer, the peeling layer 3 can be disposed at the bottommost layer, and the adhesive layer 2 is disposed between the support layer 1 and the peeling layer 3. In the following, for a clearer understanding of the present disclosure, the material characteristics of each layer in the pressure-sensitive adhesive tape 100 of the embodiment of the present disclosure will be detailed below, and the connection relationship between each layer will be explained.

### Support Layer

The support layer 1 can be, for example, a polyolefin film (i.e., a PO film) or a polyvinyl chloride film (PVC film). In terms of thickness, a first thickness D1 of the support layer 1 ranges from 50 micrometers to 180 micrometers, and preferably ranges from 80 micrometers to 150 micrometers. The polyolefin film can be made of at least one of polyethylene (PE), polypropylene (PP), polymethyl pentene (PMP), and polybutene-1 (PB-1).

Preferably, the polyolefin film can be made of polypropylene, but the present disclosure is not limited thereto.

### Adhesive Layer

The adhesive layer 2 is formed on the side surface of the support layer 1. When the peeling layer 3 is peeled off from the adhesive layer 2, the adhesive layer 2 is exposed to an external environment and can be adhered to a substrate material S to be cut.

The adhesive layer 2 can be attached to a backside of the substrate material S to be cut (e.g., a wafer, a LED substrate, a glass substrate, or a ceramic substrate) during a component cutting process. A second thickness D2 of the adhesive layer 2 ranges from 5 micrometers to 35 micrometers, and preferably ranges from 8 micrometers to 33 micrometers, but the present disclosure is not limited thereto.

Furthermore, solid components of the adhesive layer 2 include:
(a) a self-crosslinking acrylic resin;
(b) acrylate monomers or oligomers of the acrylate monomers;
(c) an isocyanate cross-linking agent; and
(d) a photo-initiator.

Based on a total weight of the solid components of the adhesive layer 2 being 100 wt %, a content of the self-crosslinking acrylic resin ranges from 50 wt % to 95 wt %, and preferably ranges from 50 wt % to 90 wt %. A content of the acrylate monomers or the oligomers ranges from 1 wt % to 40 wt %, and preferably ranges from 5 wt % to 35 wt %. A content of the isocyanate cross-linking agent ranges from 0.1 wt % to 10 wt %, and preferably ranges from 0.1 wt % to 5 wt %. Furthermore, a content of the photo-initiator ranges from 0.1 wt % to 10 wt %, and preferably ranges from 0.1 wt % to 5 wt %.

Further, the adhesive layer 2 is formed by applying a coating material that contains the aforementioned solid components and a solvent component onto the support layer 1 or the peeling layer 3, and then removing the solvent component from the coating material, but the present disclosure is not limited thereto.

### Self-Crosslinking Acrylic Resin

The self-crosslinking acrylic resin involves introducing cross-linking groups or cross-linking systems into the main chains of acrylic resin molecules. A weight average molecular weight (Mw) of the self-crosslinking acrylic resin (before being exposed to UV light) ranges from 120,000 to 650,000. The self-crosslinking acrylic resin can be formed into a polymer with a network structure through a reaction between the cross-linking groups.

The self-crosslinking acrylic resin is polymerized by at least one of following monomer components: 2-hydroxyethyl acrylate (HEA), methyl acrylate (MA), 2-methoxyethyl acrylate (MEA), acrylic acid (AA), acrylonitrile, 2-ethylhexyl methacrylate (EHA), 2-phenoxyethyl acrylate (PEA), and butyl acrylate (BA).

Further, a molecular structure of the self-crosslinking acrylic resin has at least one of following functional groups: a propylene group, a hydroxyl group, and a carboxyl group.

In one embodiment of the present disclosure, the self-crosslinking acrylic resin can be formed by introducing N-methylolacrylamide (N-MAM) and acrylic acid (AA) into an acrylic resin formed of acrylonitrile, methyl acrylate, and butyl acrylate, but the present disclosure is not limited thereto.

### Acrylate Monomers or Oligomers Thereof

The molecular structure of the acrylate monomers or the oligomers thereof has at least an alkenyl group (e.g., a vinyl group or an allyl group). The acrylate monomers can be at least one of the following compounds.

Bisphenol A dimethacrylate (referred to as bisphenol A methacrylate) has the chemical structure of:

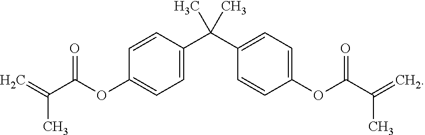 [SMILES: C=C(C)C(=O)Oc1ccc(C(C)(C)c2ccc(OC(=O)C(=C)C)cc2)cc1]

(1-methylethylidene)bis(4,1-phenyleneoxy-2,1-ethanediyl) diacrylate has the chemical structure of:

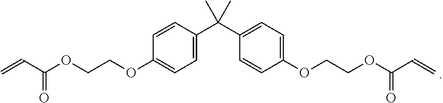 [SMILES: C=CC(=O)OCCOc1ccc(C(C)(C)c2ccc(OCCOC(=O)C=C)cc2)cc1]

Ethoxylated bisphenol A dimethacrylate has the chemical structure of:

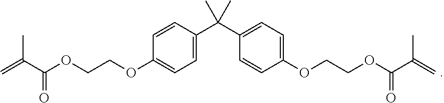 [SMILES: C=C(C)C(=O)OCCOc1ccc(C(C)(C)c2ccc(OCCOC(=O)C(=C)C)cc2)cc1]

Iso-bornyl acrylate (IBOA) has the chemical structure of:

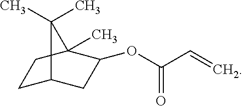

The oligomers of the acrylic monomers can be, for example, polyurethane acrylate (PUA), which has the chemical structure of:

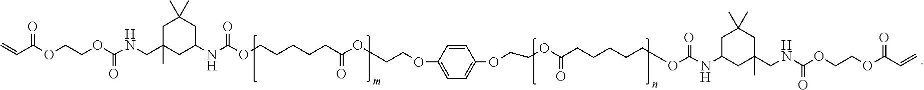

In the above chemical structure, m=3 to 20, and n=3 to 20.

In a specific embodiment of the present disclosure, the acrylate monomers are bisphenol A dimethacrylate, but the present disclosure is not limited thereto.

### Isocyanate Cross-Linking Agent

The isocyanate cross-linking agent added in the adhesive layer 2 enhances a polymerization degree of the resin composition. The isocyanate cross-linking agent can be a diisocyanate.

In some embodiments of the present disclosure, the isocyanate cross-linking agent is selected from the group consisting of: toluene diisocyanate (TDI), isophorone diisocyanate (IPDI), diphenylmethane diisocyanate (MDI), dicyclohexylmethane diisocyanate (H₁₂MDI), and lysine diisocyanate (LDI).

In a specific embodiment of the present disclosure, the isocyanate cross-linking agent is isophorone diisocyanate (IPDI).

### Photo-Initiator

The photo-initiator added in the adhesive layer 2 is capable of absorbing a radiation energy of ultraviolet light so as to undergo a chemical change to generate free radicals with abilities to initiate polymerization, so that the self-crosslinking acrylic resin, the acrylate monomers or the oligomers, and the isocyanate cross-linking agent undergo a cross-linking and curing reaction.

In some embodiments of the present disclosure, the photo-initiator is selected from the group consisting of: benzophenone, 2-hydroxy-2-methyl-1-propiophenone, 2,2-dimethoxy-1,2-diphenylethan-1-one, 1-hydroxycyclohexyl phenyl ketone, 2,4,6-trimethyl benzoyl diphenyl phosphine oxide, n-phenylglycine, 9-phenylacridine, benzoin, benzyl dimethyl ketal, 4,4′-bis(diethylamino) benzophenone, 2,4,5-tri aryl imidazole dimer.

In a specific embodiment of the present disclosure, the photo-initiator is 1-hydroxycyclohexyl phenyl ketone. For example, the photo-initiator is photoinitiator-184 (i.e., Irgacure-184), but the present disclosure is not limited thereto.

### Peeling Layer

The peeling layer 3 is peelably formed on the side surface of the adhesive layer 2 away from the support layer 1.

During a component cutting operation (e.g., a wafer dicing operation), the peeling layer 3 can be separated from the adhesive layer 2, so that the adhesive layer 2 is exposed to an external environment and can be adhered to a component to be cut (e.g., a substrate material to be cut).

In terms of thickness, a third thickness D3 of the peeling layer 3 ranges from 25 micrometers to 45 micrometers, and preferably ranges from 28 micrometers to 40 micrometers, but the present disclosure is not limited thereto.

The peeling layer 3 can be, for example, a polyester peeling layer (e.g., a PET release film).

In some embodiments of the present disclosure, the polyester peeling layer 3 can achieve a release effect by coating a silicone oil layer on a side surface of a polyester film or by adding an inorganic material into the polyester film to reduce the adhesion of the side surface of the polyester film.

### De-Glued Mechanism of UV Light

In terms of de-glued mechanism of UV light, the photo-initiator added in the adhesive layer 2 is capable of absorbing the radiation energy of ultraviolet light so as to undergo the chemical change to generate the free radicals with the abilities to initiate polymerization, so that the self-crosslinking acrylic resin, the acrylate monomers or the oligomers, and the isocyanate cross-linking agent undergo the cross-linking and curing reaction. Therefore, the adhesion of the adhesive layer is reduced.

Before being exposed to ultraviolet (UV) light, the adhesive layer 2 has a certain level of adhesiveness with the substrate to be cut (e.g., a wafer, a LED substrate, a glass substrate, or a ceramic substrate), which can prevent the substrate from falling off after being cut (e.g., preventing the dice or chips from detaching).

After being exposed to ultraviolet (UV) light for a predetermined time, the adhesion of the adhesive layer 2 decreases due to the cross-linking and curing reaction, thereby achieving the effect of UV de-glued, so as to prevent the occurrence of stickiness or adhesive residue on the cut component after the cut component is separated from adhesive layer 2.

A wavelength of an ultraviolet (UV) light source can be, for example, between 300 nanometers and 380 nanometers, preferably between 340 nanometers and 380 nanometers, and more preferably between 360 nanometers and 375 nanometers, but the present disclosure is not limited thereto.

An irradiation energy of the ultraviolet light source irradiated on the adhesive layer 2 is greater than 300 mJ/cm² and less than 2,000 mJ/cm², preferably greater than 500 mJ/cm² and less than 1,500 mJ/cm², and more preferably greater than 500 mJ/cm² and less than 1,000 mJ/cm².

An irradiation time of the ultraviolet light source irradiated on the adhesive layer 2 ranges from 5 seconds to 2 minutes, preferably ranges from 10 seconds to 1 minute, and more preferably ranges from 10 seconds to 45 seconds, but the present disclosure is not limited thereto.

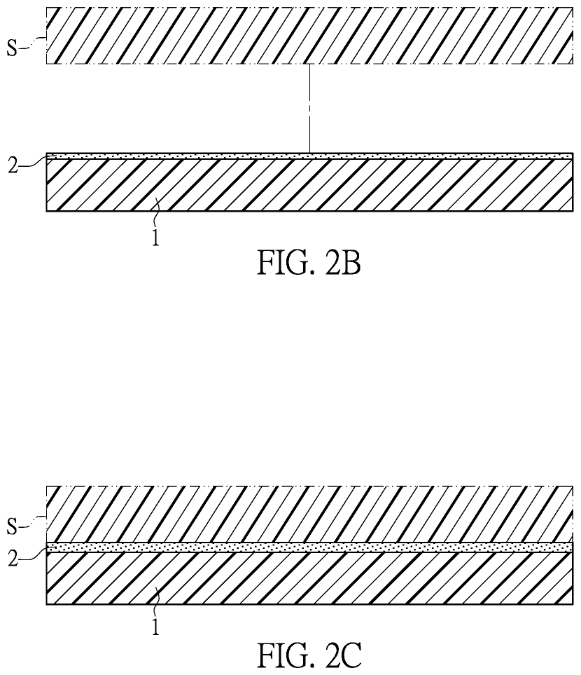

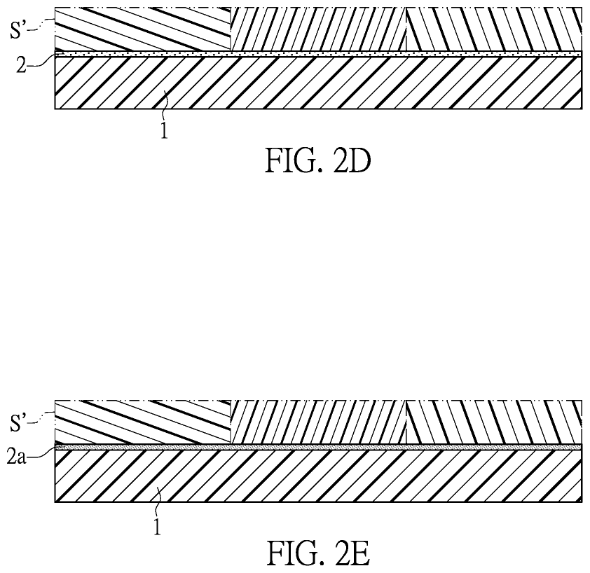

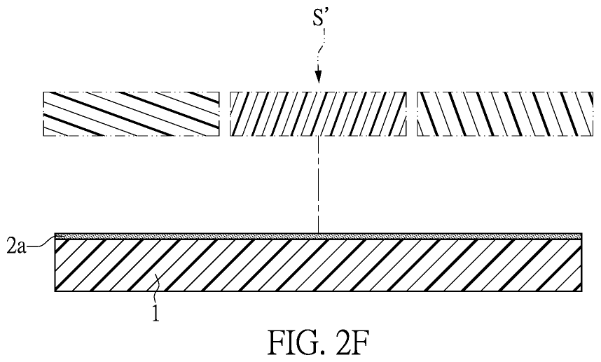

Furthermore, the adhesive layer 2 is configured to be attached to a substrate material S to be cut during a component cutting process as shown in FIG. 2C. Before the adhesive layer 2 is irradiated by ultraviolet light, a first peeling strength between the adhesive layer 2 and the substrate S to be cut ranges from 200 gf/inch to 2,500 gf/inch. That is, the adhesive layer 2 has a high bonding strength with the substrate S to be cut before being irradiated by ultraviolet light.

After the adhesive layer 2 is irradiated by ultraviolet light, the self-crosslinking acrylic resin, the acrylate monomers or the oligomers of the acrylate monomers, and the isocyanate cross-linking agent in the adhesive layer 2 undergo a cross-linking and curing reaction, so as to form an irradiated adhesive layer 2a as shown in FIG. 2E.

In the present embodiment, a second peeling strength between the irradiated adhesive layer 2a and the substrate material S′ that has been cut (e.g., die or dice) ranges from 10 gf/inch to 75 gf/inch, which represents a decrease of 75% to 99.9% compared to the first peeling strength.

That is, the bonding strength between the irradiated adhesive layer 2a and the substrate material S′ that has been cut is greatly reduced after irradiation. Therefore, the irradiated adhesive layer 2a can be easily peeled off from the substrate material S′ that has been cut without any residual adhesive being remained on the substrate material S′.

The first peeling strength and the second peeling strength can be measured according to ASTM D3330. For example, the test method is performed by rolling the adhesive layer 2 back and forth with a roller so as to attach the adhesive layer 2 onto the substrate material S to be cut, and then the test can be carried out after the adhesive layer stops being rolled with the roller. The substrate material is fixed on a lower fixture, the sample is folded at 180 degrees and fixed on an upper fixture, the adhesive layer 2 is peeled off from the substrate material at a predetermined speed (e.g., 300 mm/min), and an average value during peeling is measured. The peeling strength is recorded in units of N/inch.

Overall, the adhesive layer 2 absorbs radiation energy of ultraviolet (UV) light through the photo-initiator, and the photo-initiator undergoes a chemical change to generate free radicals capable of initiating polymerization, so that the self-crosslinking acrylic resin, the acrylate monomers or the oligomers, and the isocyanate cross-linking agent undergo the cross-linking and curing reaction, thereby achieving the effect of being de-glued. Moreover, a significant difference in the peeling strengths before and after UV irradiation is performed, which provides a wide range of peeling force adjustment.

It is worth mentioning that the self-crosslinking acrylic resin and the acrylate monomers (or the oligomers thereof) play an important role in the adhesive layer 2, which enables the adhesive layer 2 to exhibit a significant difference in peeling strengths before and after exposure to ultraviolet (UV) light.

If the adhesive layer 2 does not include the self-crosslinking acrylic resin or the acrylate monomers specified in the embodiment of the present disclosure, the difference in peeling strengths before and after UV irradiation would be smaller, which could result in the adhesive residues on the substrate surface when the tape is peeled off, and similarly, issues such as adhesive residue and debonding may occur after exposure.

### Method for Producing Pressure-Sensitive Adhesive Tape

The above embodiment is a description of the material and structural features of the pressure-sensitive adhesive tape, and the following will continue to explain a method for producing a pressure-sensitive adhesive tape according to an embodiment of the present disclosure. The method includes step S110, step S120, and step S130.

It must be noted that the sequence of the various steps and the actual operation mode described in the embodiment of the present disclosure can be adjusted according to practical requirements, and are not limited to the embodiment described in the present disclosure.

Step S110 includes: providing a peeling layer 3. The peeling layer 3 can be, for example, a polyester peeling layer (e.g., a PET release film).

Step S120 includes: applying a coating material (e.g., an adhesive glue composition onto a side surface of the peeling layer 3, and removing the solvent component from the coating material, thereby forming an adhesive layer 2 on the side surface of the peeling layer 3.

In step S120, the coating material can be applied onto the peeling layer 3 by roller coating, screen printing, gravure coating, or off-line coating. Subsequently, by subjecting the coating material to a solvent removal or curing process, the coating material is formed into a film, thereby forming the adhesive layer 2.

The coating material (e.g., the adhesive glue coating composition) includes solid components and at least a solvent component for mixing the solid components. The solid components include (a) a self-crosslinking acrylic resin, (b) acrylate monomers or oligomers of the acrylate monomers, (c) an isocyanate cross-linking agent, and (d) a photo-initiator, as mentioned in the above embodiment. The material characteristics and formulations of the solid components are as described in the above embodiment and will not be reiterated herein.

The solvent component is used to dilute the solid components, enabling the coating material to have a predetermined viscosity, thereby facilitating easier application of the coating material onto the peeling layer 3 and aiding in formation. A weight ratio between the solvent component and the solid components ranges from 5:95 to 30:70. The solvent component can be, for example, at least one of ethyl acetate (EAC) and methyl ethyl ketone (MEK). Preferably, the solvent component is ethyl acetate, but the present disclosure is not limited thereto.

It is worth mentioning that the acrylate monomers or the oligomers thereof do not undergo a cross-linking and curing reaction before being irradiated by ultraviolet (UV) light, so that the adhesive layer 2 can maintain a higher adhesive strength for better conformity with the substrate material S to be cut. Furthermore, after being irradiated by the ultraviolet light, the adhesive layer 2 undergoes the cross-linking and curing reaction, significantly reducing the adhesive strength of the adhesive layer 2. Accordingly, the adhesive layer 2 is easy to be separated from the substrate material.

Step S130 includes: attaching a support layer 1 (e.g., a support film) to a side surface of the adhesive layer 2 away from the peeling layer 3, thus completing the preparation of the pressure-sensitive adhesive tape 100.

It should be noted that although the present embodiment is described in such a way that the adhesive layer 2 is firstly formed on the peeling layer 3, and then the support layer 1 is attached to the adhesive layer 2, the present disclosure is not limited thereto. For example, in another embodiment, the adhesive layer 2 can be firstly formed on the support layer 1, and then the peeling layer 3 is attached to the adhesive layer 2.

### Method for Using Pressure-Sensitive Adhesive Tape

The above embodiments are the descriptions of the material and structural features of the pressure-sensitive adhesive tape and the method for producing the pressure-sensitive adhesive tape, and the following will continue to explain a method for using a pressure-sensitive adhesive tape according to an embodiment of the present disclosure.

The method for using the pressure-sensitive adhesive tape includes step S210, step S220, step S230, step S240, step S250, and step S260.

It must be noted that the sequence of the various steps and the actual operation mode described in the embodiment of the present disclosure can be adjusted according to practical requirements, and are not limited to the embodiment described in the present disclosure.

As shown in FIG. 2A, step S210 includes: providing the pressure-sensitive adhesive tape 100 as described above, and peeling off the peeling layer 3 of the pressure-sensitive adhesive tape 100 from the side surface of the adhesive layer 2, so that the adhesive layer 2 is exposed to an external environment.

As shown in FIG. 2B, step S220 includes: providing a substrate material S to be cut (e.g., a wafer), and orienting the adhesive layer 2 of the pressure-sensitive adhesive tape 100 to face toward the substrate material S to be cut.

As shown in FIG. 2C, step S230 includes: attaching the adhesive layer 2 of the pressure-sensitive adhesive tape 100 to the substrate material S to be cut, in which a first peeling strength between the adhesive layer 2 and the substrate material S to be cut ranges from 200 gf/inch to 2,500 gf/inch.

As shown in FIG. 2D, step S240 includes: performing a cutting operation on the substrate material S to be cut, such that the side surface of the substrate material S to be cut away from adhesive layer 2 is cut, so as to form a substrate material S′ that has been cut (e.g., a wafer being cut into multiple small dice or chips that contains integrated circuits).

As shown in FIG. 2E, step S250 includes: irradiating the adhesive layer 2 of the pressure-sensitive adhesive tape 100 by an ultraviolet light source, so that the photo-initiator added in the adhesive layer 2 absorbs radiation energy of the ultraviolet light source, and generates free radicals with abilities to initiate polymerization.

Accordingly, the self-crosslinking acrylic resin, the acrylate monomers or the oligomers thereof, and the isocyanate cross-linking agent undergo a cross-linking and curing reaction so as to form an irradiated adhesive layer 2a that has a reduced adhesion.

In some embodiments of the present disclosure, a wavelength of the ultraviolet (UV) light source ranges from 300 nanometers to 380 nanometers. An irradiation energy of the ultraviolet light source irradiated on the adhesive layer 2 is greater than 300 mJ/cm² and less than 2,000 mJ/cm², and an irradiation time of the ultraviolet light source irradiated on the adhesive layer 2 ranges from 5 seconds to 2 minutes, but the present disclosure is not limited thereto.

In the present embodiment, a second peeling strength between the irradiated adhesive layer 2a and the substrate material S′ that has been cut ranges from 10 gf/inch to 75 gf/inch, which represents a decrease of 75% to 99.9% compared to the first peeling strength.

That is, the bonding strength between the irradiated adhesive layer 2a and the substrate material S′ that has been cut is greatly reduced after irradiation. Therefore, the irradiated adhesive layer 2a can be easily peeled off from the substrate material S′ that has been cut without any residual adhesive remaining thereon.

As shown in FIG. 2F, step S260 includes: separating the substrate material S′ that has been cut from the irradiated adhesive layer 2a, so that the substrate material S′ can be divided into multiple small pieces of material (e.g., multiple small dice or chips that contain integrated circuits).

According to the above configuration, the pressure-sensitive adhesive tape 100 provided in the embodiment of the present disclosure can adhere strongly to the substrate material S to be cut, with the adhesive layer 2 firmly attaching to the substrate material S without falling off. During the cutting operation, the adhesive layer 2 may not experience debonding or produce stringing of the adhesive.

After exposure to ultraviolet (UV) light, the adhesive strength between the irradiated adhesive layer 2a and the substrate material S′ that has been cut is significantly reduced. Therefore, the irradiated adhesive layer 2a can be easily peeled off from the substrate material S′ without leaving any adhesive residue.

### Experimental Data and Test Results

To verify the technical effects of the pressure-sensitive adhesive tape provided by the embodiment of the present disclosure, the following will describe the experimental data and results, but the present disclosure is not limited thereto.

In Exemplary Example 1, a coating material is prepared and contains 50 parts by weight of a self-crosslinking acrylic resin (i.e., 10AM, full name HT-6455UH-10AM, purchased from Shin Zong Industrial Co., Ltd.), 25 parts by weight of acrylate monomers (i.e., bisphenol A dimethacrylate), 0.5 parts by weight of an isocyanate cross-linking agent (i.e., iso-phorone diisocyanate, IPDI), 0.3 parts by weight of a photo-initiator (i.e., Irgacure-184), and 24.2 parts by weight of solvent (i.e., ethyl acetate, EAC). The coating material is coated onto a polyester release film (i.e., a PET release film), and the solvent in the coating material is removed, thereby forming an adhesive layer having a thickness of 10 micrometers on the polyester release film. A support layer (i.e., a polypropylene support layer) is attached to a side surface of the adhesive layer away from the polyester release film, so as to complete the preparation of the pressure-sensitive adhesive tape.

The preparation methods of the pressure-sensitive adhesive tapes of Exemplary Examples 2 to 7 are substantially the same as that of Exemplary Example 1. The difference lies in the preparation conditions and test results of the adhesive layer, which are listed in Table 1 below.

The preparation methods of the pressure-sensitive adhesive tapes of Comparative Examples 1 to 3 are roughly the same as that of Exemplary Example 1. The main difference is that the adhesive layers of Comparative Examples 1 to 3 do not include acrylate monomers. The conditions and test results are listed in Table 2 below.

Among the self-crosslinking acrylic resins as shown in Table 1 and Table 2, is 10AM, the full name of which is HT-6455UH-10AM, which is purchased from Shin Zong Industrial Co., Ltd. The full name of SD-488 is an UV debonding acrylic adhesive, which is purchased from Nan Pao Materials Vietnam Co., Ltd. Furthermore, the full name of NC22 is a UV debonding glue, which is purchased from VISTAWIDE Co., Ltd.

The pressure-sensitive adhesive tapes prepared in Exemplary Examples 1 to 7 and Comparative Examples 1 to 3 are tested by removing the peeling layer and attaching the adhesive layer to a substrate material to be cut (i.e., a wafer).

The peeling strength between the adhesive layer and the substrate material is tested before and after exposure to ultraviolet (UV) light, and the presence of any adhesive residue on the substrate material is observed.

The peeling strength is tested by firstly rolling the adhesive layer back and forth with a roller on the substrate material to be cut, and stopping rolling of the adhesive layer, so that the peeling strength between the adhesive layer and the substrate material can be tested.

The test method of the peeling strength adopts ASTM D3330. The unit of peeling strength is recorded in gf/inch.

The test results include the peeling strengths before and after UV irradiation. In the test, the irradiation energy of UV light is 500 mJ/cm², and the irradiation time is 15 seconds.

TABLE 1
Exemplary Examples 1 to 7

| | | Exemplary | Exemplary | Exemplary | Exemplary | Exemplary | Exemplary | Exemplary |
|---|---|---|---|---|---|---|---|---|
| | | Example 1 | Example 2 | Example 3 | Example 4 | Example 5 | Example 6 | Example 7 |
| Preparation | Amount of self- | 50 | 65 | 70 | 70 | 70 | 68 | 68 |
| conditions | crosslinking | | | | | | | |
| of | acrylic resin | | | | | | | |
| adhesive | (parts by weight) | | | | | | | |
| layer | Type of self- | 10AM | 10AM | SD-488 | SD-488 | SD-488 | NC22 | NC22 |
| | crosslinking | | | | | | | |
| | acrylic resin | | | | | | | |
| | Amount of | 25 | 10 | 15 | 20 | 15 | 5 | 10 |
| | acrylate | | | | | | | |
| | monomers (parts | | | | | | | |
| | by weight) | | | | | | | |
| | Type of acrylate | bisphenol | bisphenol | bisphenol | bisphenol | bisphenol | bisphenol | bisphenol |
| | monomers | A di-meth- | A di-meth- | A di-meth- | A di-meth- | A di-meth- | A di-meth- | A di-meth- |
| | | acrylate | acrylate | acrylate | acrylate | acrylate | acrylate | acrylate |
| | Amount of | 0.5 | 0.5 | 0.7 | 0.7 | 0.7 | 0.3 | 0.3 |
| | isocyanate cross- | | | | | | | |
| | linking agent | | | | | | | |
| | (parts by weight) | | | | | | | |
| | Type of | IPDI | IPDI | IPDI | IPDI | IPDI | Tri-HDI | Tri-HDI |
| | isocyanate cross- | | | | | | | |
| | linking agent | | | | | | | |
| | Amount of photo- | 0.3 | 0.3 | 0.3 | 0.3 | 0.3 | 0.5 | 0.5 |
| | initiator (parts by | | | | | | | |
| | weight) | | | | | | | |
| | Type of photo- | I184 | I184 | I184 | I184 | I184 | I184 | I184 |
| | initiator | | | | | | | |
| | Amount of | 24.2 | 24.2 | 14 | 9 | 14 | 26.2 | 21.2 |
| | solvent (parts by | | | | | | | |
| | weight) | | | | | | | |
| | Type of solvent | Eac | Eac | Eac | Eac | Eac | Eac | Eac |
| | Thickness of | 10 | 10 | 20 | 20 | 30 | 10 | 10 |
| | adhesive layer | | | | | | | |
| | (micrometers) | | | | | | | |
| Test | Peeling strength | 850 | 500 | 1,200 | 2,200 | 1,900 | 270 | 600 |
| Results | (gf/inch) before | | | | | | | |
| | being irradiated | | | | | | | |
| | by UV light | | | | | | | |
| | Peeling strength | 45 | 35 | 45 | 52 | 48 | 40 | 70 |
| | (gf/inch) after | | | | | | | |
| | being irradiated | | | | | | | |
| | by UV light | | | | | | | |
| | Observation of | No | No | No | No | No | No | No |
| | residual adhesive | | | | | | | |

TABLE 2
Comparative Examples 1 to 3

| | | Comparative | Comparative | Comparative |
|---|---|---|---|---|
| | | Example 1 | Example 2 | Example 3 |
| Preparation | Amount of self-crosslinking | 62 | 70 | 73 |
| conditions of | acrylic resin (parts by weight) | | | |
| adhesive | Type of self-crosslinking acrylic | 10AM | SD-488 | NC22 |
| layer | resin | | | |
| | Amount of acrylate monomers | — | — | — |
| | (parts by weight) | | | |
| | Type of acrylate monomers | — | — | — |
| | Amount of isocyanate cross- | 0.5 | 0.7 | 0.3 |
| | linking agent (parts by weight) | | | |
| | Type of isocyanate cross-linking | IPDI | IPDI | Tri-HDI |
| | agent | | | |
| | Amount of photo-initiator (parts | 0.3 | 0.3 | 0.5 |
| | by weight) | | | |
| | Type of photo-initiator | I184 | I184 | I184 |
| | Amount of solvent (parts by | 37.2 | 29 | 26.2 |
| | weight) | | | |
| | Type of solvent | Eac | Eac | Eac |
| | Thickness of adhesive layer | 10 | 20 | 20 |
| | (micrometers) | | | |
| Test | Peeling strength | 370 | 730 | 430 |
| Results | (gf/inch) before being irradiated | | | |
| | by UV light | | | |
| | Peeling strength | 220 | 365 | 275 |
| | (gf/inch) after being irradiated by | | | |
| | UV light | | | |
| | Observation of adhesive residual | adhesive residual | adhesive residual | No (high peeling |
| | | | | strength after being |
| | | | | irradiated by UV |
| | | | | light) |

The pressure-sensitive adhesive tapes prepared in Exemplary Examples 1 to 7 have high peeling strength (i.e., 270 gf/inch to 2,200 gf/inch) before UV irradiation. Especially, in each of Exemplary Examples 1 and 3 to 5, the amount of acrylate monomers adopts 15 parts by weight to 25 parts by weight, the peeling strength before UV irradiation is relatively high (i.e., 850 gf/inch to 2,200 gf/inch). In addition, the peeling strength of each of the pressure-sensitive adhesive tapes prepared in Exemplary Examples 1 to 7 is reduced significantly (i.e., reduced to 30 gf/inch to 75 gf/inch) after UV irradiation. Furthermore, after the pressure-sensitive adhesive tape prepared in each of Exemplary Examples 1 to 7 is separated from the substrate material, no adhesive residue remains, so as to be particularly suitable for use in wafer dicing operations during a semiconductor manufacturing process.

It is worth mentioning that in Exemplary Examples 1 and 3 to 5, the weight ratio between the self-crosslinking acrylic resin and the acrylate monomers is between 50:25 and 70:15, which enable the pressure-sensitive adhesive tape to have better peeling strength difference before and after UV irradiation.

On the other hand, the pressure-sensitive adhesive tapes prepared in Comparative Examples 1 to 3 have common peeling strengths (i.e., 370 gf/inch to 730 gf/inch) before UV irradiation. In addition, the peeling strengths of the pressure-sensitive adhesive tapes prepared in Comparative Examples 1 to 3 do not drop significantly (i.e., reduced to 220 gf/inch to 365 gf/inch) after UV irradiation, and is not reduced by more than 50%. After the pressure-sensitive adhesive tapes prepared in Comparative Examples 1 to 3 are separated from the substrate materials, some of the substrate materials have residual adhesive, and some of the adhesive layers are not easily separated from the substrate materials due to high peeling strength after UV irradiation, which can easily cause damage to the semiconductor dice.

### Beneficial Effects of the Embodiments

In conclusion, in the pressure-sensitive adhesive tape, the method for producing the same, and the method for using the same provided by the present disclosure, by virtue of “solid components of the adhesive layer including a self-crosslinking acrylic resin, acrylate monomers or oligomers of the acrylate monomers, an isocyanate cross-linking agent, and a photo-initiator,” and “before the adhesive layer is irradiated by ultraviolet light, the acrylate monomers or the oligomers not undergoing a cross-linking and curing reaction,” and “after the adhesive layer is irradiated by the ultraviolet light, the photo-initiator generating free radicals with abilities to initiate polymerization, and the self-crosslinking acrylic resin, the acrylate monomers or the oligomers, and the isocyanate cross-linking agent undergo the cross-linking and curing reaction, so that an adhesion of the adhesive layer is reduced,” the pressure-sensitive adhesive tape of the present disclosure can overcome the issues of dice drop-off during the semiconductor cutting operation and the dice being difficult to be peeled off from the carrier substrate after UV exposure.

The pressure-sensitive adhesive tape provided by the present disclosure can be de-glued by UV light and is particularly suitable for use in a semiconductor wafer processing process, so as to facilitate pickup of the dice.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A pressure-sensitive adhesive tape, comprising:
a support layer;
an adhesive layer being formed on a side surface of the support layer; wherein solid components of the adhesive layer include:
a self-crosslinking acrylic resin;
acrylate monomers or oligomers of the acrylate monomers;
an isocyanate cross-linking agent; and
a photo-initiator; and
a peeling layer being peelably formed on a side surface of the adhesive layer away from the support layer;
wherein, before the adhesive layer is irradiated by ultraviolet light, the acrylate monomers or the oligomers do not undergo a cross-linking and curing reaction;
wherein, after the adhesive layer is irradiated by the ultraviolet light, the photo-initiator generates free radicals with abilities to initiate polymerization, and the self-crosslinking acrylic resin, the acrylate monomers or the oligomers, and the isocyanate cross-linking agent undergo the cross-linking and curing reaction, so that an adhesion of the adhesive layer is reduced.

2. The pressure-sensitive adhesive tape according to claim 1, wherein, based on a total weight of the solid components of the adhesive layer being 100 wt %, a content of the self-crosslinking acrylic resin ranges from 50 wt % to 95 wt %, a content of the acrylate monomers or the oligomers ranges from 1 wt % to 40 wt %, a content of the isocyanate cross-linking agent ranges from 0.1 wt % to 10 wt %, and a content of the photo-initiator ranges from 0.1 wt % to 10 wt %.

3. The pressure-sensitive adhesive tape according to claim 2, wherein the content of the self-crosslinking acrylic resin ranges from 50 wt % to 90 wt %, the content of the acrylate monomers or the oligomers ranges from 5 wt % to 35 wt %, the content of the isocyanate cross-linking agent ranges from 0.1 wt % to 5 wt %, and the content of the photo-initiator ranges from 0.1 wt % to 5 wt %.

4. The pressure-sensitive adhesive tape according to claim 1, wherein the self-crosslinking acrylic resin is polymerized by at least one of following monomer components: 2-hydroxyethyl acrylate (HEA), methyl acrylate (MA), 2-methoxyethyl acrylate (MEA), acrylic acid (AA), acrylonitrile, 2-ethylhexyl methacrylate (EHA), 2-phenoxyethyl acrylate (PEA), and butyl acrylate (BA); wherein a molecular structure of the self-crosslinking acrylic resin has at least one of following functional groups: a propylene group, a hydroxyl group, and a carboxyl group.

5. The pressure-sensitive adhesive tape according to claim 1, wherein the acrylate monomers or the oligomers are selected from the group consisting of: bisphenol A dimethacrylate, (1-methylethylidene)bis(4,1-phenyleneoxy-2,1-ethanediyl) diacrylate, ethoxylated bisphenol A dimethacrylate, iso-bornyl acrylate, and urethane acrylate.

6. The pressure-sensitive adhesive tape according to claim 1, wherein the isocyanate cross-linking agent is a diisocyanate, which is selected from the group consisting of: toluene diisocyanate (TDI), isophorone diisocyanate (IPDI), diphenylmethane diisocyanate (MDI), dicyclohexylmethane diisocyanate (H₁₂MDI), and lysine diisocyanate (LDI).

7. The pressure-sensitive adhesive tape according to claim 1, wherein the photo-initiator is selected from the group consisting of: benzophenone, 2-hydroxy-2-methyl-1-propiophenone, 2,2-dimethoxy-1,2-diphenylethan-1-one, 1-hydroxycyclohexyl phenyl ketone, 2,4,6-trimethyl benzoyl diphenyl phosphine oxide, n-phenylglycine, 9-phenylacridine, benzoin, benzyl dimethyl ketal, 4,4′-bis(diethylamino) benzophenone, and 2,4,5-tri aryl imidazole dimer.

8. A method for producing a pressure-sensitive adhesive tape, comprising:
providing a peeling layer;
applying a coating material on a side surface of the peeling layer; wherein the coating material includes solid components and at least a solvent component for mixing the solid components; wherein the solid components include a self-crosslinking acrylic resin, acrylate monomers or oligomers of the acrylate monomers, an isocyanate cross-linking agent, and a photo-initiator; wherein the solvent component is at least one of ethyl acetate and methyl ethyl ketone; wherein a weight ratio between the solvent component and the solid components ranges from 5:95 to 30:70;
removing the solvent component from the coating material to form an adhesive layer on the side surface of the peeling layer; and
attaching a support layer on a side surface of the adhesive layer away from the peeling layer to form the pressure-sensitive adhesive tape;
wherein the peeling layer is peelable from the adhesive layer, so that the adhesive layer is capable of being exposed to an external environment and being bonded to a substrate material to be cut;
wherein, before the adhesive layer is irradiated by ultraviolet light, the acrylate monomers or the oligomers do not undergo a cross-linking and curing reaction;
wherein, after the adhesive layer is irradiated by the ultraviolet light, the photo-initiator generates free radicals with abilities to initiate polymerization, and the self-crosslinking acrylic resin, the acrylate monomers or the oligomers, and the isocyanate cross-linking agent undergo the cross-linking and curing reaction, so that an adhesion of the adhesive layer is reduced.

9. A method for using a pressure-sensitive adhesive tape, comprising:
providing the pressure-sensitive adhesive tape as claimed in claim 1;
peeling off the peeling layer of the pressure-sensitive adhesive tape from the side surface of the adhesive layer, so that the adhesive layer is exposed to an external environment;
providing a substrate material to be cut, and orienting the adhesive layer of the pressure-sensitive adhesive tape to face toward the substrate material to be cut;
attaching the adhesive layer of the pressure-sensitive adhesive tape to the substrate material to be cut; wherein a first peeling strength between the adhesive layer and the substrate material to be cut ranges from 200 gf/inch to 2,500 gf/inch;
performing a cutting operation on the substrate material to be cut to form a substrate material that has been cut;
irradiating the adhesive layer of the pressure-sensitive adhesive tape by an ultraviolet light source, so that the photo-initiator generates the free radicals with the abilities to initiate the polymerization, and the self-crosslinking acrylic resin, the acrylate monomers or the oligomers, and the isocyanate cross-linking agent undergo the cross-linking and curing reaction so as to reduce the adhesion of the adhesive layer;
wherein, after the adhesive layer is irradiated by the ultraviolet light source, a second peeling strength between the adhesive layer and the substrate material that has been cut ranges from 10 gf/inch to 75 gf/inch.

10. The method for using the pressure-sensitive adhesive tape according to claim 9, wherein a wavelength of the ultraviolet light source ranges from 300 nanometers to 380 nanometers, an irradiation energy of the ultraviolet light source irradiated on the adhesive layer is greater than 300 mJ/cm² and less than 2,000 mJ/cm², and an irradiation time of the ultraviolet light source irradiated on the adhesive layer ranges from 5 seconds to 2 minutes.
